(19) United States
(12) Patent Application Publication
(10) Pub. No.: US 2026/0241323 A1
(43) Pub. Date: Aug. 20, 2026

(54) MOBILE TOXIC GAS PURIFICATION DEVICE

(71) Applicant: HANSO INC., Daejeon (KR)

(72) Inventors: Sang Woong KIM, Daejeon (KR); Eun Ju LEE, Daejeon (KR); Chang Ick LEE, Cheongju-si (KR)

(73) Assignee: HANSO INC., Daejeon (KR)

(21) Appl. No.: 19/161,761

(22) PCT Filed: Feb. 29, 2024
(86) PCT No.: PCT/KR2024/002631

§ 371 Date: Sep. 3, 2025

(30) Foreign Application Priority Data
Mar. 3, 2023 (KR) 10-2023-0028384

(51) Int. Cl. B01D 53/04; B01D 46/00; B01D 46/44

(52) U.S. Cl. CPC B01D 53/0446; B01D 46/0036; B01D 46/0047; B01D 46/442; B01D 53/0415; B01D 53/0454; B01D 2257/93; B01D 2259/402; B01D 2259/4558; B01D 2279/40

(57) ABSTRACT

The present invention relates to a mobile purification device, and the mobile purification device of the present invention is operated by a battery, so that purification of toxic gases may be made without limitations on location or space, and an adsorbent may be replaced for a toxic gases to be purified, so that various types of toxic gases may be efficiently purified.

### CROSS-REFERENCE TO RELATED APPLICATIONS

This application is a 35 U.S.C. § 371 national phase of PCT International Application No. PCT/KR 2024/002631, filed Feb. 29, 2024, which claims the benefit of priority under 35 U.S.C. § 119 to Korean Patent Application No. 10-2023-0028384, filed Mar. 3, 2023, the content of which is incorporated herein by reference in its entirety.

### TECHNICAL FIELD

The present invention relates to a mobile toxic gases purification device, and more particularly, to a mobile toxic gases purification device, allowing mobility and portability, capable of purifying toxic gases without being restricted by location or space.

### BACKGROUND

Toxic gases emitted from chemical processes, semiconductor manufacturing processes, and various industrial sites are highly toxic, explosive, and corrosive, posing a risk to the human body, and may cause environmental pollution when released into the atmosphere. Therefore, in order to purify these toxic gases, intake and exhaust systems using air conditioning ducts and dampers are installed in semiconductor manufacturing processes and various industrial sites to exhaust toxic gases occurring in enclosed spaces, such as factories and chambers, to the outside and draw outside air into the interior and circulate the air, thereby purifying the internal air.

Korean Application Publication No. 10-2017-0063088 discloses an air purification device which primarily removes harmful elements in the air, such as volatile organic compound (VOC) gases, through a thermal catalytic reaction, as well as filters various types of fine dust and particulate matter, and secondarily and tertiarily removes harmful viruses and bacteria in the air by supplying sterilizing water and irradiating with ultraviolet light to maintain pleasant indoor air and prevent air pollution. This device is capable of automatically removing harmful gases occurring in enclosed spaces at various industrial sites, including semiconductor production sites.

However, the related art air purification device is required to be fixedly installed in exhaust pipes, limiting purification to designated areas, and is not portable or mobile and impossible to be applied to various spaces.

An object of the present invention is to provide a portable, a mobile toxic gases purification device which is movable and portable.

In one general aspect, a mobile purification device includes: a case including an intake port intaking toxic gases on one side and a discharge port discharging the intaken air after purifying the air on the other side; a plurality of flow path portions separating toxic gases intaken through the intake port; a plurality of purification units independently provided in the plurality of flow path portions, respectively, to purify the toxic gases; a path determination unit provided at a branch point of the plurality of flow path portions based on a concentration of the toxic gases and determining a path for the toxic gases to flow to one of the plurality of purification units; a distribution unit connected to the path determination unit and distributing the toxic gases to flow into one of the plurality of purification units; and a power supply unit having a rechargeable battery installed within the case.

The mobile purification device according to the present invention includes a battery compartment, allowing workers to drag the mobile purification device around in narrow and confined spaces of various industrial sites, including semiconductor production sites, to adsorb and filter toxic gases, thereby effectively purifying toxic gases without limitations on location or space.

Furthermore, the mobile purification device according to the present invention includes replaceable adsorbents within the first and second canisters, depending on the type of toxic gases to be purified, thereby enabling purification of a variety of toxic gases.

Furthermore, in the mobile purification device according to the present invention, when the adsorbent within either of the first or second canisters reaches its usable limit, toxic gases may flow into either the first or second canister, thereby improving purification efficiency.

### BRIEF DESCRIPTION OF THE DRAWINGS

FIG. 1 is a structural diagram of a mobile purification device of the present invention.

FIG. 2 is a schematic diagram of a mobile purification device of the present invention.

FIG. 3 is a front view of a mobile purification device of the present invention.

FIG. 4 is a rear view of a mobile purification device of the present invention.

FIG. 5 is a plan view of a mobile purification device of the present invention.

FIG. 6 is an actual photograph of a mobile purification device of the present invention.

### DETAILED DESCRIPTION

The mobile purification device of the present invention includes: a case including an intake port intaking toxic gases on one side and a discharge port discharging the intaken air after purifying the air on the other side; a plurality of flow path portions separating toxic gases intaken through the intake port; a plurality of purification units independently provided in the plurality of flow path portions, respectively, to purify the toxic gases; a path determination unit provided at a branch point of the plurality of flow path portions based on a concentration of the toxic gases and determining a path for the toxic gases to flow to one of the plurality of purification units; a distribution unit connected to the path determination unit and distributing the toxic gases to flow into one of the plurality of purification units; and a power supply unit having a rechargeable battery installed within the case.

The distribution unit includes a valve controller controlling a valve provided in the distribution unit to control an amount of toxic gases flowing into one of the plurality of purification units.

The plurality of purification units include a first purification unit and a second purification unit connected to one of the plurality of flow path portions.

The first purification unit includes: a first canister adsorbing toxic gases flowing in from one of the plurality of flow paths; a first filter filtering the toxic gases adsorbed from the first canister; and a first blower exhausting the toxic gases filtered from the first filter to the outside.

The second purification unit includes: a second canister adsorbing toxic gases flowing in from one of the plurality of flow path portions; a second filter filtering the toxic gases adsorbed from the second canister; and a second blower exhausting the toxic gases filtered from the second filter to the outside.

The first canister and the second canister include a replaceable adsorbent depending on a type of air to be purified inside the first canister and the second canister.

The case further includes an exhaust space separating the first filter and the first blower and the second filter and the second blower for filtering and exhausting toxic gases adsorbed from the first canister and the second canister within the case.

The exhaust space further includes a detection unit detecting a concentration of toxic gases remaining in the purified air before the purified air is exhausted through the exhaust port.

The detection unit further includes a detection controller that, if the concentration of toxic gases remaining in the purified air is not detected, exhausts the purified air through the discharge port, and, if the concentration of toxic gases remaining in the purified air is detected, activates either one of the first canister or the second canister provided in the purification unit.

The exhaust space communicates with the exhaust port of the case.

The case includes: a display portion located outside the case, measuring a concentration of gas discharged from the discharge port, and displaying the measured concentration of the gas; a warning unit warning whether a toxic gases exceeding a preset concentration is detected by the detection unit; a first canister mounting portion on which the first canister is mounted; and a second canister mounting portion on which the second canister is mounted.

The display portion further includes a battery display portion displaying a charging status of a battery provided in the power supply unit.

The case includes a wheel provided at the bottom of the case to enable movement.

Hereinafter, the present invention will be described in more detail below through specific examples or exemplary embodiments including the accompanying drawings. However, the following specific examples or exemplary embodiments are only a reference for describing the present invention in detail, and the present invention is not limited thereto and may be implemented in various forms.

In addition, unless otherwise defined, all technical and scientific terms have the same meaning as commonly understood by a person skilled in the art to which the present invention pertains. The terms used in the description herein are only for effectively describing a certain example, and are not intended to limit the present invention.

Further, the singular form used in the specification and attached claims may also include the plural forms, unless otherwise stated in the context.

Further, when it is mentioned that an element “includes” another element, this means that the element may further include still another element without excluding still another element unless oppositely described.

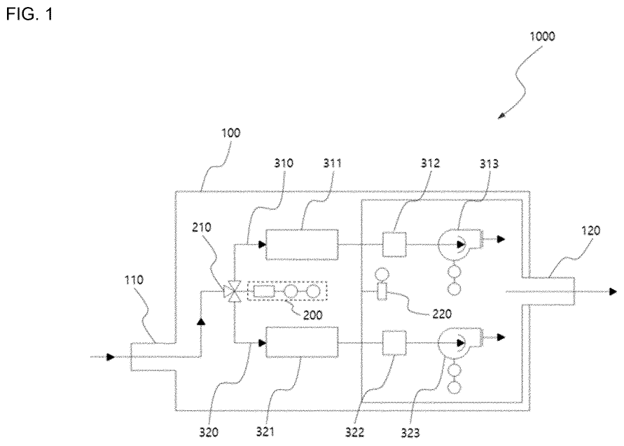

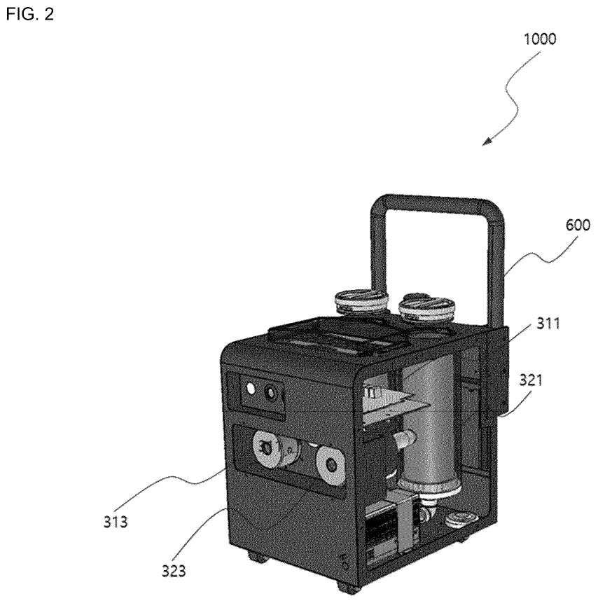

FIG. 1 is a structural diagram of a mobile purification device according to the present invention, and FIG. 2 is a schematic diagram of a mobile purification device according to the present invention. Referring to FIGS. 1 and 2, a mobile purification device 1000 of the present invention includes a case 100, a flow path portion 300, a purification unit, a path determination unit 200, a distribution unit 210, and a power supply unit.

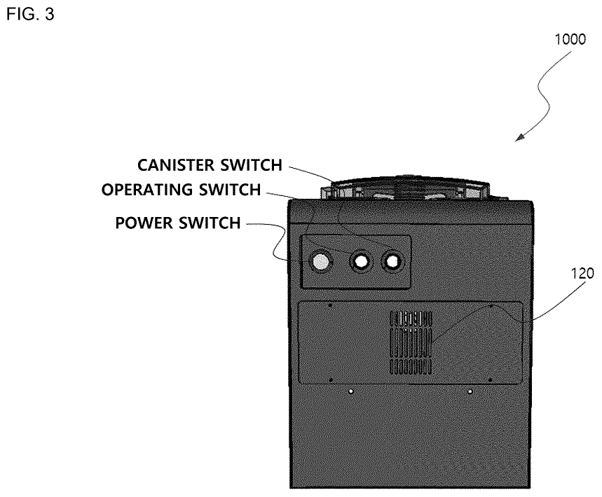

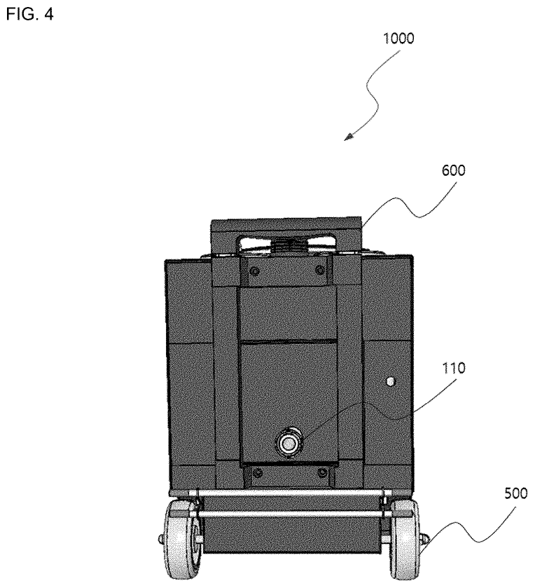

FIG. 3 is a front view of a mobile purification device of the present invention, and FIG. 4 illustrates a rear view of a mobile purification device of the present invention. Referring to FIGS. 3 and 4, the case 100 is formed with an intake port 110 on one side to intake toxic gases and a discharge port 120 on the other side to purify and discharge the intaken air. The case 100 may be formed of materials, such as stainless steel or reinforced plastic and have an internal space for receiving components. Toxic gases occurring outside are intaken through the intake port 110 of the case 100 and adsorbed within the case 100, and purified air is discharged to the outside through the discharge port 120 of the case 100. Here, the intake port 110 may further include an intake tube capable of intaking toxic gases. The intake tube may be formed within the intake port 110 to directly intake external toxic gases, thereby further improving the intake efficiency of toxic gases.

Next, the toxic gases intaken through the intake port 110 flows into a plurality of flow path portions 300. The plurality of flow path portions 300 separate the paths of the toxic gases intaken through the intake port 110. The plurality of flow path portions 300 are provided with a plurality of purification units, each independently installed within the plurality of flow path portions 300 to purify the toxic gases.

The purification unit includes a canister, a filter, and a blower. The canister includes a replaceable adsorbent capable of adsorbing toxic gases therein and is configured to adsorb introduced toxic gases. In addition, the toxic gases are filtered once more in the filter before being discharged as purified air through adsorption in the canister, thereby removing any residual toxic gases or residual fine particles. The air filtered in the filter is discharged to the discharge port 120 through the blower. In addition, the purification unit is provided in plurality and includes a first purification unit and a second purification unit connected to any one of the plurality of flow path portions 300. Here, the first purification unit is configured to include a first canister 311 that adsorbs toxic gases flowing in from any one of the plurality of flow path portions 300, a first filter 312 that filters the toxic gases adsorbed from the first canister 311, and a first blower 313 that exhausts the toxic gases filtered from the first filter 312 to the outside. The second purification unit is configured to include a second canister 321 that adsorbs toxic gases flowing in from any one of the plurality of flow path portions 300, a second filter 322 that filters the toxic gases adsorbed from the second canister 321, and a second blower 323 that exhausts the toxic gases filtered from the second filter 322 to the outside. In addition, the first canister 311 and the second canister 321 include an adsorbent replaceable depending on the type of toxic gases to be purified.

Furthermore, the plurality of flow path portions 300 through which toxic gases is supplied to the intake port 110 of the housing further include the path determination unit 200 and the distribution unit 210 to control the toxic gases flowing into the first purification unit and the second purification unit connected to any one of the plurality of flow path portions 300. The path determination unit 200 is provided at a branch point of the plurality of flow path portions 300 based on the concentration of the toxic gases and determines a path to transport the toxic gases to any one of the plurality of purification units. When toxic gases flows into the intake port 110, the toxic gases may flow into either the first canister 311 or the second canister 321 including an adsorbent therein. Here, when the adsorbent provided inside either the first canister 311 or the second canister 321 reaches its usable limit, the path may be determined by the path determination unit 200 so that the toxic gases may flow into either the first canister 311 or the second canister 321. In addition, the path determination unit 200 includes the distribution unit 210 that is connected to the path determination unit 200 and distributes the toxic gases to flow into either one of a plurality of purification units. The distribution unit 210 includes a valve controller that controls a valve provided in the distribution unit 210 to control the amount of the toxic gases flowing into either one of the plurality of purification units. To increase the intake efficiency of the toxic gases controlled by the distribution unit 210, the amount of toxic gases flowing into either the first canister 311 or the second canister 321 may be controlled or blocked. By controlling the amount of toxic gases flowing into the first canister 311 or the second canister 321, the purification efficiency of the first canister 311 or the second canister 321 may be improved.

Furthermore, the case 100 further includes an exhaust space separating a first filter 312 and a first blower 313 and the second filter 322 and the second blower 323 that filter and exhaust the toxic gases adsorbed from the first canister 311 and the second canister 321 therein. The exhaust space further includes a detection unit 220 that detects the concentration of toxic gases remaining in the purified air before the purified air is exhausted through the exhaust port. The detection unit 220 further includes a detection controller that exhausts the purified air through the exhaust port if the concentration of toxic gases remaining in the purified air is not detected and that operates the second canister 321 provided in the purification unit if the concentration of toxic gases remaining in the purified air is detected. Here, the detection unit 220 detects the concentration of the purified air exhausted to the exhaust space. If the detection unit 220 does not detect residual toxic gases in the purified air, the purified air is exhausted to the discharge port. Here, the exhaust space communicates with the exhaust port of the case 100. Since the exhaust space communicates with the exhaust port, the toxic gases flowing in from an inlet may be prevented from mixing with the air purified in the exhaust space, and the concentration of residual toxic gases may be accurately recognized by the detecting unit 220, and thus, purification may be more efficiently performed. In addition, when residual toxic gases is detected in the purified air by the detection unit 220, any one of the first canister 311 or the second canister 321 may be operated by the detection controller, so that the residual toxic gases may be re-purified and exhausted through the exhaust port.

Furthermore, the first canister 311 and the second canister 321 include an adsorbent therein. The adsorbent may be replaced depending on the type of toxic gases to be purified. For example, when the toxic gases to be purified in the first canister 311 and the second canister 321 are two types of a first toxic gases and a second toxic gases, the first canister 311 may include an adsorbent capable of purifying the first toxic gases, and the second canister 321 may include an adsorbent capable of purifying the second toxic gases, and thus, the first canister 311 and the second canister 321 may be operated alternately to purify the toxic gases.

Next, the mobile purification device 1000 further includes a power supply unit (not shown), and the power supply unit (not shown) includes a rechargeable battery installed within the case 100. The power supply unit (not shown) may further include a charging unit capable of recharging the battery. Furthermore, referring to the rear view of the mobile purification device of the present invention in FIG. 4, the mobile purification device 1000 includes mobile wheels 500 at the bottom of the mobile purification device 1000 and a handle 600 at the top, allowing for free movement and includes a power supply unit (not shown) equipped with a battery, allowing workers to drag the mobile purification device 1000 around in narrow, confined spaces of various industrial sites including semiconductor manufacturing sites, while adsorbing and filtering toxic gases, thereby enabling purification of toxic gases without limitations in location or space.

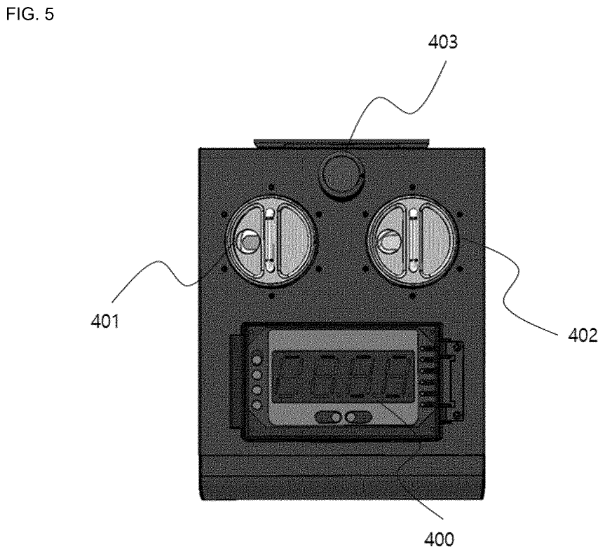

FIG. 5 is a plan view of a mobile purification device of the present invention. Referring to FIG. 5, the mobile purification device 1000 of the present invention includes a display portion 400, a first canister mounting portion 401, and a second canister mounting portion 402 located outside the case 100.

The display portion 400 measures the concentration of gas discharged from the discharge port 120 and displays the measured gas concentration. Here, air filtered within the mobile purification device 1000 is discharged through the discharge port 120 via a blower, and here, the concentration of toxic gases measured by the detection unit 220 may be displayed on the display portion 400, and by checking the measured gas concentration displayed on the display portion 400 as to whether the filtered air includes toxic gases before the filtered gas is discharged, whether air has been purified may be determined.

In addition, the first canister 311 is mounted on the first canister mounting portion 401, and the second canister 321 is mounted on the second canister mounting portion 402. Since the adsorbent within the first canister 311 and the second canister 321 may be replaced depending on the type of toxic gases to be purified, the first canister 311 and the second canister 321 may be separated through the first canister mounting portion 401 and the second canister mounting portion 402 and an appropriate adsorbent may be replaced and used depending on the type of toxic gases to be purified, thereby enabling the purification of various toxic gases.

Furthermore, the display portion 400 further includes a battery display portion (not shown) that displays a charge status of the battery provided in the power supply unit. The battery charge status may be checked in real time using the battery display portion (not shown), and thus, toxic gases may be purified simply and rapidly by charging the battery without limitations on location or space.

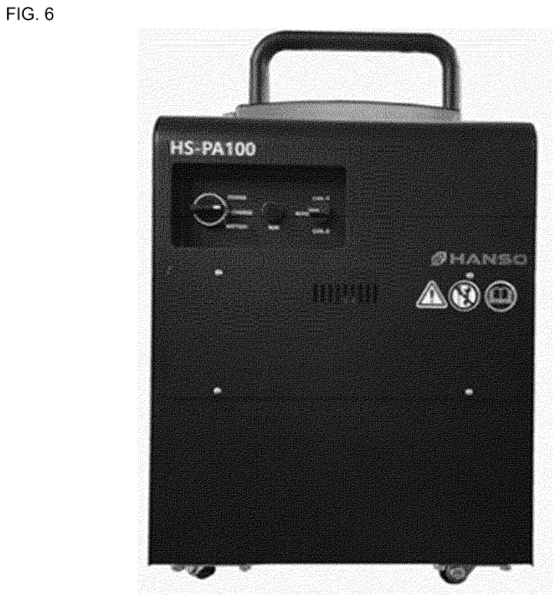

FIG. 6 is an actual photograph of a mobile purification device of the present invention. Referring to FIG. 6, the mobile purification device of the present invention includes the mobile wheels 500 on the bottom and the handle 600 on the top, allowing for free movement, and also includes the power supply unit including the battery, allowing workers to drag the mobile purification device around in narrow, confined spaces of various industrial sites including semiconductor production sites, to adsorb and filter toxic gases, enabling purification of toxic gases without limitations on location or space.

The present invention is not limited to the above-described exemplary embodiments, the scope of application is diverse, and various modifications and variations may be made without departing from the spirit of the invention as claimed in the claims.

The mobile purification device of the present invention allows workers to drag the mobile purification device around in narrow, confined spaces of various industrial sites including semiconductor production sites, to adsorb and filter toxic gases, enabling rapid, easy, and low-cost purification of toxic gases without limitations on location or space.

1. A mobile purification device comprising:
a case including an intake port intaking toxic gases on one side and a discharge port discharging the intaken air after purifying the air on the other side;
a plurality of flow path portions separating toxic gases intaken through the intake port;
a plurality of purification units independently provided in the plurality of flow path portions, respectively, to purify the toxic gases;
a path determination unit provided at a branch point of the plurality of flow path portions based on a concentration of the toxic gases and determining a path for the toxic gases to flow to one of the plurality of purification units;
a distribution unit connected to the path determination unit and distributing the toxic gases to flow into one of the plurality of purification units; and
a power supply unit having a rechargeable battery installed within the case.

2. The mobile purification device of claim 1, wherein the distribution unit includes a valve controller controlling a valve provided in the distribution unit to control an amount of toxic gases flowing into one of the plurality of purification units.

3. The mobile purification device of claim 1, wherein the plurality of purification units include a first purification unit and a second purification unit connected to one of the plurality of flow path portions.

4. The mobile purification device of claim 3, wherein the first purification unit includes:
a first canister adsorbing toxic gases flowing in from one of the plurality of flow path portions;
a first filter filtering the toxic gases adsorbed from the first canister; and
a first blower exhausting the toxic gases filtered from the first filter to the outside.

5. The mobile purification device of claim 4, wherein the second purification unit includes:
a second canister adsorbing toxic gases flowing in from one of the plurality of flow paths;
a second filter filtering the toxic gases adsorbed from the second canister; and
a second blower exhausting the toxic gases filtered from the second filter to the outside.

6. The mobile purification device of claim 4, wherein the first canister and the second canister include a replaceable adsorbent depending on a type of air to be purified inside the first canister and the second canister.

7. The mobile purification device of claim 1, wherein the case further includes an exhaust space separating the first filter and the first blower and the second filter and the second blower for filtering and exhausting toxic gases adsorbed from the first canister and the second canister within the case.

8. The mobile purification device of claim 7, wherein the exhaust space further includes a detection unit detecting a concentration of toxic gases remaining in the purified air before the purified air is exhausted through the exhaust port.

9. The mobile purification device of claim 8, wherein the detection unit further includes a detection controller that, if the concentration of toxic gases remaining in the purified air is not detected, exhausts the purified air through the discharge port, and, if the concentration of toxic gases remaining in the purified air is detected, activates either one of the first canister or the second canister provided in the purification unit.

10. The mobile purification device of claim 8, wherein the exhaust space communicates with the exhaust port of the case.

11. The mobile purification device of claim 1, wherein the case includes:
a display portion located outside the case, measuring a concentration of gas discharged from the discharge port, and displaying the measured concentration of the gas;
a warning unit warning whether a toxic gases exceeding a preset concentration is detected by the detection unit;
a first canister mounting portion on which the first canister is mounted; and
a second canister mounting portion on which the second canister is mounted.

12. The mobile purification device of claim 11, wherein the display portion further includes a battery display portion displaying a charging status of a battery provided in the power supply unit.

13. The mobile purification device of claim 1, wherein the case includes a wheel provided at the bottom of the case to enable movement.
